(19) United States
(12) Patent Application Publication
(10) Pub. No.: US 2022/0050129 A1
(43) Pub. Date: Feb. 17, 2022

(54) NON-CONTACT DETECTOR

(71) Applicant: G.l. Mcgavin Pty Ltd, Lambton (AU)

(72) Inventors: Darrell Morris, Lambton (AU); Ashley Morris, Marks Point (AU); Chris Starkey, Waratah West (AU)

(21) Appl. No.: 17/413,217

(22) PCT Filed: Dec. 11, 2019
(86) PCT No.: PCT/AU2019/051364

§ 371 Date: Jun. 11, 2021

(30) Foreign Application Priority Data
Dec. 13, 2018 (AU) 2018904737

(51) Int. Cl. G01R 19/155; G01R 15/14; G08B 7/06; G08B 21/18

(52) U.S. Cl. CPC G01R 19/155; G08B 21/18; G08B 7/06; G01R 15/14

(57) ABSTRACT

A detector 1 detects the presence of a charged object due to a static or DC voltage source 4. The detector 1 includes a sensor 30 positioned in an electric field 3 emanating from the DC voltage source 4. A sensor signal 20 is processed by a processor 21, and, when the DC voltage source 4 is detected, the processor 21 produces an alert signal to warn a user of a potentially hazardous situation.

### BACKGROUND OF THE INVENTION

The present invention relates to the detection of the presence of a charge on an object, and in particular, to a non-contact detector which is adapted to detect and warn a user of the presence of a potentially dangerous static voltage/charge on an object.

The device of the present invention may typically be embodied as a hand-held device used by rescue personnel, to warn a user of the presence of an electrocution threat or a potentially hazardous DC voltage source present on or near an electric vehicle, solar installation, tram line or any other equipment which may potentially be a source of DC power.

### DESCRIPTION OF THE PRIOR ART

Any reference herein to known prior art does not, unless the contrary indication appears, constitute an admission that such prior art is commonly known by those skilled in the art to which the invention relates, at the priority date of this application.

Non-contact detectors for detecting the presence of an AC voltage sources are presently known. One such device is commercialised by G. L McGavin, and is known as the ‘Modiewark Rescue’ detector.

The ‘Modiewark Rescue’ detector device is particularly useful for fire and rescue personnel to detect if and when an AC voltage source is present, such that such personnel may avoid contact with the AC voltage or any object which may be conductively connected thereto and which could otherwise lead to serious injury or death.

The “Modiewark Rescue’ device, when placed within an electric field emanating from an AC voltage source, provides an audio alert as well as a visual alert signal to a user by lighting up an array of LEDs.

In use, a rescue personnel or other user will typically hold the ‘Modiewark Rescue’ detector device and point it towards any potentially dangerous AC voltage source with an outstretched arm, so that when the device is activated, the device will produce an alert signal if the detected AC voltage exceeds a predetermined threshold.

Whilst the ‘Modiewark Rescue’ detector, and other like detectors are presently known, these devices are only able to detect the presence of AC voltages, as they function by detecting the electromagnetic field emanating from the AC voltage source.

Whilst devices such as the ‘Modiewark Rescue’ detector are therefore extremely useful to detect whether dangerously AC high voltages may be present in situations which may potentially pose a risk to rescue personnel or other users, they cannot be used to detect equivalent dangerous situations as a result of the presence of high levels of DC voltage.

However, with the recent advent of DC electric cars, and DC solar power systems, etc. there is an ever-increasing risk incidence of persons being potentially exposed to dangerous levels of DC voltage.

At present, the only way of effectively determining the presence of a potentially dangerous DC voltage source is to use a DC voltage detector in the form of a meter, which requires physically contacting the voltage source with a probe or the like.

As this requires physically contacting the DC voltage source, this has obvious drawbacks, requiring extreme care to ensure that a user is properly insulated in performing the task.

This therefore identifies a need to overcome these disadvantages of being able to readily identify a potentially dangerous DC voltage source.

### SUMMARY OF THE INVENTION

The present invention seeks to overcome the drawbacks of the prior art, by providing a non-contact sensor, for the detection of a static voltage or charge.

The present invention also seeks to provide a detector which, in use, may be held by a user and pointed towards a DC voltage source, such that the user is warned if a potentially dangerous DC voltage source is detected.

In one broad for, the present invention provides a non-contact detector adapted to detect and warn a user of the presence of an object charged by a static voltage source, the detector including:
a housing, adapted to be hand held by the user to be positioned proximal to, but without contacting, the object;
   a sensor within said housing, said sensor configured to sense an electric field emanating from the object and generate a sensor signal indicative of the strength of any sensed electric field waves;
   a processor within said housing, adapted to receive said sensor signal from said sensor, and produce an alert signal indicative of the magnitude of the sensed electric field; and
an alert indicator on said housing, adapted to provide an indication to the user of the magnitude of the charge on the object.

Preferably, said static voltage source includes a DC Voltage source or a static charge on said object having been charged by friction and/or a DC voltage source.

Also preferably, said sensor includes:
a sensor plate adapted to sense said electric waves emanating from the DC voltage source; and,
a shutter disposed proximal to the sensor, adapted to periodically impede said electric field waves being received on said sensor plate.

Also preferably, said sensor includes a sensor plate adapted to periodically conduct and thereby generate said sensor signal.

Preferably, said sensor includes a sensor plate adapted to periodically move/vibrate in a direction substantially to and from said DC voltage source, so as to generate said sensor signal.

Also preferably, said alert indicator is adapted to provide an audible, visual and/or haptic alert signal to said user.

Preferably, the detector further includes a controller, adapted to control a periodic operation of the shutter and/or sensor plate.

Preferably, said controller includes a motor adapted to operate said shutter to thereby periodically substantially block said sensor plate from sensing said electric field emanating from said DC voltage source.

Preferably, said shutter includes a circular disc having at least one opening therein which is adapted to be rotated by a shaft of said motor, such that, as said shutter rotates, the electric field emanating from a DC voltage source is periodically permitted to pass through said opening(s) such that said sensor plate periodically accumulates charge and subsequently discharges to thereby generate said sensor signal.

Also preferably, said processor processes said sensor signal and correlates it with data received from said controller to thereby determine a magnitude of the electric field emanating from said DC voltage source.

Preferably, said alert indicator includes an array of lights, LEDs or the like to provide a visual indication of the magnitude of the DC voltage source.

Also preferably, said detector includes a sensitivity selection switch, for user selection according to the magnitude of the DC voltage source being detected.

Preferably, the detector further includes a detector adapted to detect the presence of an AC voltage source.

In a further broad form, the present invention provides a non-contact DC voltage detector adapted to detect and warn a user of the presence of a DC voltage, the detector including:
a housing, adapted to be hand held by the user to be positioned proximal to a DC voltage source;
a sensor within said housing, said sensor configured to sense an electric field emanating from said DC voltage source and generate a sensor signal indicative of the strength of the sensed electric field waves;
a processor within said housing, adapted to receive said sensor signal from said sensor, and produce an alert signal indicative of the magnitude of said DC voltage source; and
an alert indicator on said housing, adapted to provide an indication to the user of the magnitude of the DC voltage source.

Preferably, the sensor includes:
a sensor plate adapted to sense said electric waves emanating from the DC voltage source; and,
a shutter disposed proximal to the sensor, adapted to periodically impede said electric field waves being received on said sensor plate.

Also preferably, said sensor includes a sensor plate adapted to periodically conduct and thereby generate said sensor signal.

Preferably, said sensor includes a sensor plate adapted to periodically move/vibrate in a direction substantially to and from said DC voltage source, so as to generate said sensor signal.

Also preferably, said alert indicator is adapted to provide an audible and/or a visual alert signal to said user.

Preferably, the detector further includes a controller, adapted to control a periodic operation of the shutter and/or sensor plate.

Preferably, said controller includes a motor adapted to operate said shutter to thereby periodically substantially block said sensor plate from sensing said electric field emanating from said DC voltage source.

Also preferably, said shutter includes a circular disc having at least one opening therein which is adapted to be rotated by a shaft of said motor, such that, as said shutter rotates, the electric field emanating from a DC voltage source is periodically permitted to pass through said opening(s) such that said sensor plate periodically accumulates charge and subsequently discharges to thereby generate said sensor signal.

Also preferably, said processor processes said sensor signal and correlates it with data received from said controller to thereby determine a magnitude of the electric field emanating from said DC voltage source.

Preferably, said alert indicator includes an array of lights, LEDs or the like to provide a visual indication of the magnitude of the DC voltage source.

Preferably, said detector includes a sensitivity selection switch, for user selection according to the magnitude of the DC voltage source being detected.

Preferably, the detector further includes a detector adapted to detect the presence of an AC voltage source.

In a further broad form, the present invention provides a detector adapted to detect the presence of both an AC and a DC voltage source.

### BRIEF DESCRIPTION OF THE DRAWINGS

The present invention will become more fully understood from the following detailed description of preferred but non-limiting embodiments thereof, described in connection with the accompanying drawings, wherein:

FIG. 1 illustrates a user using a detector device in accordance with a preferred embodiment of the present invention;

FIG. 2 illustrates a typical front face of one preferred implementation of the detector, showing the various buttons and indicator lights, etc. displayed to a user;

FIG. 3 shows a schematic representation of a preferred embodiment of the main component features of the present invention;

FIG. 4 illustrates an alternative, but also preferred embodiment of a hand-held detector device of the present invention; and,

FIG. 5 illustrates, in FIGS. 5(a) to 5(h) thereof, various representations showing various details of the embodiment of the detector device shown in FIG. 4.

### DETAILED DESCRIPTION OF THE EMBODIMENT OR EMBODIMENTS

Throughout the drawings, like numerals will be utilised to represent like features, except where expressing otherwise indicated.

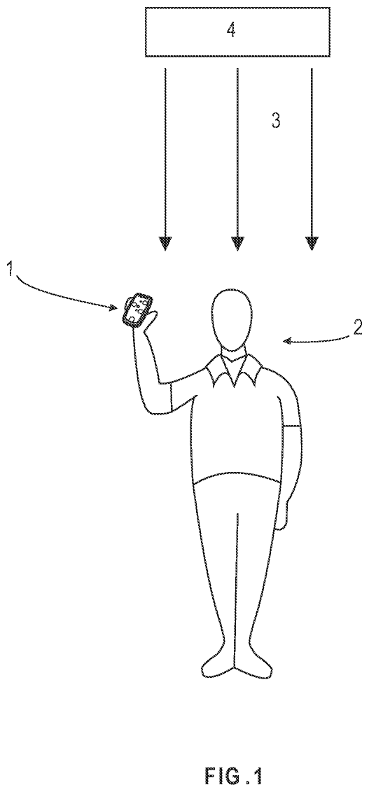

FIG. 1 shows a DC detector 1 in accordance with the present invention, being held by a user 2 to detect the presence of an electric field 3 emanating from a DC voltage source 4.

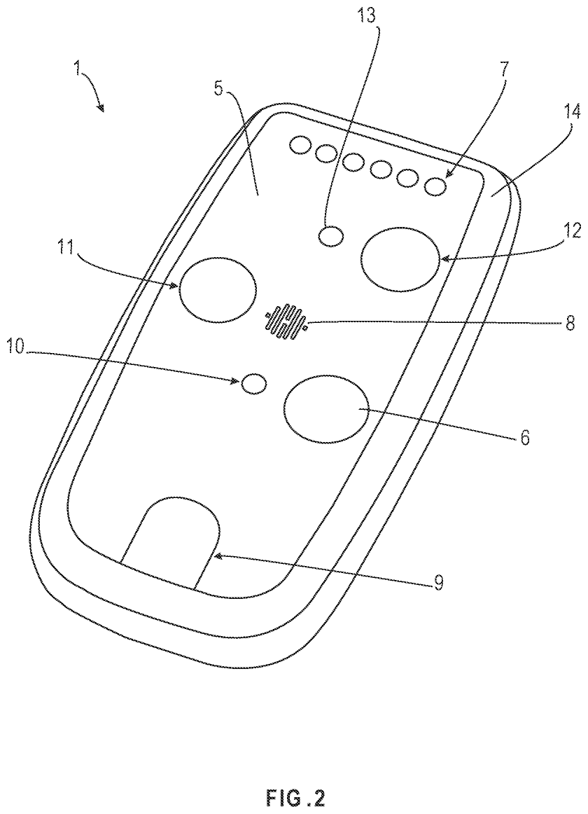

The front face 5 of a first preferred embodiment of a housing 14 of the DC detector 1 is shown in FIG. 2. The detector 1 includes various switches and displays which are available for the user 2 to operate the device 1, and, to receive appropriate audio and/or visual alert signals, if the detector 1 detects the presence of a DC voltage source, and/or, that the DC voltage levels are above a predetermined threshold indicative of a hazardous situation.

In particular, the typical features which may be provided on the front face 5 of the DC detector housing 14 may include an on/off switch 6, and, a series of LEDs or the like 7 which may provide a visual indication of a detected DC voltage to a user 2, and, a speaker 8 to provide an audible alert signal or alarm to the user 2.

Additional, optional features may include a sensor pad 9, upon which a user's thumb might typically be placed, in order to activate the detector 1 after the on/off switch 6 is turned on, and when a user is ready to use the device to detect the presence of a DC voltage source 4.

Additional indicators may be provided, such as an indicator light 10, which may, for example, flash green to indicate that the device is powered on, and flash red if the battery is low.

A self-test button 11 may optionally also be provided for a user to run a test routine, to test that the device is properly working.

Alternatively, or additionally, a DC generator, for instance a hand-held DC generator, may be used to test the correct operation of the device

In some instances, it may be desired to detect more sensitive voltage sources, so provision for this may be provided via a high sensitivity switch 12 and an associated indicator light 13, such that a more sensitive reading may be taken by a user. The indicator light 13 may, for example, flash green for a more sensitive reading and red for a less sensitive reading.

It will be appreciated by persons skilled in the art that these switches are only provided as exemplary features, and, may be optionally provided in some alternative embodiments of the invention. Likewise, other additional features may be provided, if desired, such features being apparent to persons skilled in the art.

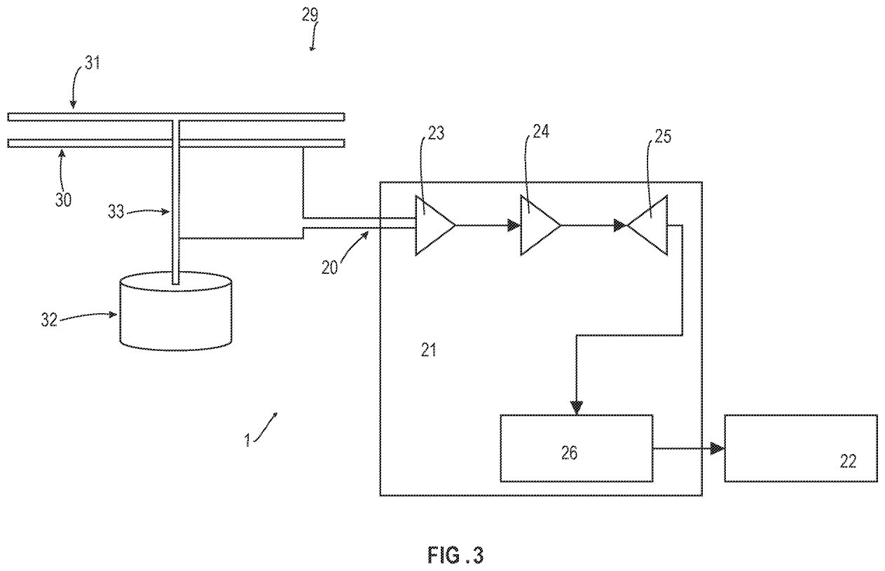

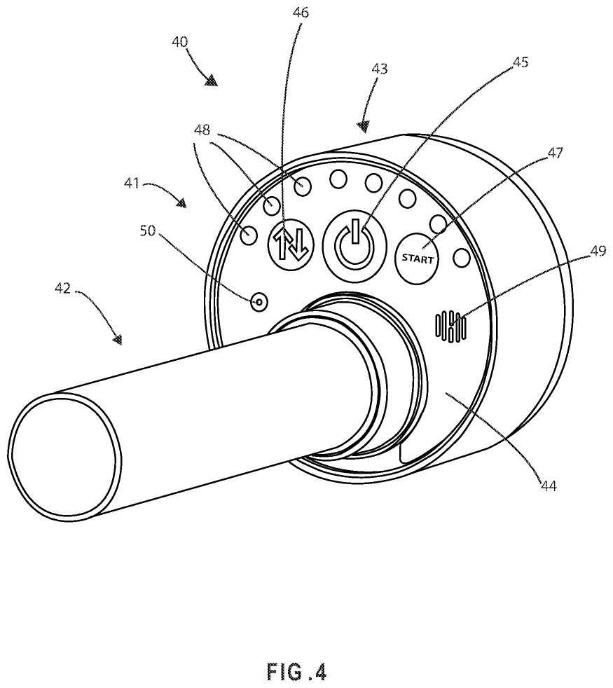

FIG. 3 illustrates a schematic representation of a preferred but not limited embodiment of the present invention.

In the embodiment shown in FIG. 3, the detector, generally designated by the numeral 1, is adapted to detect the presence of a DC voltage source. The detector 1, includes a sensor, generally designated by the numeral 29, which is adapted to be positioned in an electric field emanating from the DC voltage source (as shown in FIG. 1), and, generate a sensor signal 20 in response thereto.

The sensor signal 20 is conveyed via an input to a processor 21. The processor 21 is adapted to process the sensor signal 20 and provide a visual/audible warning to a user on indicator 22 when the device 1 is positioned proximal to the DC voltage source 2. The alert indicator 22 is preferably adapted to provide an alert signal in the form of a visual or audible signal to a user 2 when the DC voltage source 4 is sensed and/or exceeds a predetermined threshold indicative of a hazardous or dangerous situation.

The sensor 29 may take a variety of forms, but, in essence is configured to periodically receive waves of an electric field 3 emanating from the DC voltage source 4.

The embodiment illustrated in FIG. 3 shows a sensor 29 which includes a sensor plate 30 which is adapted to receive waves from an electric field emanating from the DC voltage source 4.

In one embodiment, the sensor 29 may also include a shutter 31 which is disposed intermediate the sensor plate 30 and the DC voltage source 4. In operation, the shutter 31 is adapted to periodically impede the electric waves 3 being received on the sensor plate 30. This may be achieved, for example, by spinning the shutter 31, moving the shutter 31 back and forth, etc.

It will be understood by persons skilled in the art that this periodic reception of the waves 3 of the electric field on the sensor plate 30 will therefore generate a sensor signal 20 which may be conveyed to the processor 21.

It will also be understood by persons skilled in the art that the sensor plate 30 could be embodied in a variety of alternative forms, to simulate this periodic pickup of the electric field 3.

This could, for example, be achieved by the sensor plate 30 being adapted to periodically conduct and thereby receive the electric field 4 and thereby generate a sensor signal 20. An alternative configuration of a sensor may include a sensor plate which is adapted to move or vibrate periodically. If this sensor plate is moved or vibrated in a direction which is towards or away from the DC voltage source, then this will enable pickup of the electric field 3 so as to generate a sensor signal 20.

The detector 1 of the present invention may, in accordance with a first preferred embodiment of the invention, be typically embodied within a housing 14, such as shown in FIG. 2. The housing 14 incorporates the processor 21, and, preferably also includes various indicators to provide alerts to the user 2. For example, the housing 14 illustrated in FIG. 2 provides an audio alert means via a speaker 8 which may, for example, provide a piercing or buzzing sound to a user 2 in the event of a dangerous DC voltage being proximal to the device 1. Likewise, a visual indicator, via an array of LEDs 7 may be provided to provide a visual indication of there being a DC voltage detected by the device 1.

The array of LEDs 7 may indicate the strength of the electric field 3 which would be proportional to strength of the DC voltage source 4. Of course, an array of LEDs 7 does not necessarily be provided, but instead, a simple indicator light merely indicating that the voltage is above a certain threshold could alternatively be provided.

Alternatively, or additionally, a haptic device may be incorporated, which would produce a haptic or mechanical vibration effect to the user to indicate the detection of a DC voltage.

The detector device 1 of the present invention may be housed in the form of a handheld device, such as shown in FIG. 2, or, it may be embodied as a body-worn device. For example, a body-worn device could be in the form of a watch, or a necklace. Alternatively, the detector could be integrally formed in a body-worn garment. This could be, for example, embedded in the sleeve or cuff of a shirt, on a belt, a hat, or, on any other garment worn by a user 2. The device may also be embodied in the form of a watch worn by the user, or a device worn around the neck of the user.

Referring to FIG. 3, it will be appreciated that the sensor shown may typically generate an analogue sensor signal 20 which may be proportional to the strength of the detected electric field 3. This analogue sensor signal 20 may then be processed by the processor 21 to ultimately provide via the alert indicator 22 an audible, visual and/or vibration alert signal to the user. This analogue signal may be processed utilising any appropriate circuitry or algorithm, as will be readily understood by persons skilled in the art.

Typically, the sensor signal 20 may be initially processed by a preamplifier 23, followed by an appropriate filter and amplifier 24 to eliminate stray signals or unwanted signals. The circuitry may then process the signal from an analogue to a digital signal in an analogue to digital converter 25, before being further processed using a magnitude detection algorithm in a processor 26. In the event of the detected voltage being above or below a certain threshold, an appropriate visual alert signal or audible alert signal may be provided to the user via visual audible indicator 26.

In the sensor shown in FIG. 3, it will be understood that the shutter arrangement may be driven by a motor 32 which is connected to the shutter 31 via a shaft 33, whereby rotation of the motor 32 facilitates rotation of the shutter 31. The shutter 31 may be in the form of a plate provided with one or more openings therein, such that, as the shutter 31 rotates, the electric field 3 is periodically able to be detected via the sensor plate 30.

That is, the shutter 31 may be embodied as a circular disk having at least one opening therein which, when rotated by the shaft 33 of the motor 32, allows the electric field 3 emanating from the DC voltage source 4 to periodically pass through the opening(s).

During this operation, the sensor plate 30 periodically accumulates charge and subsequently discharges to thereby generate the sensor signal 20.

It will be appreciated that the openings may be in the form of apertures, orifices or any other form of openings, without limitation. It will further be understood that one such opening could be provided in the rotating shutter 31, or a polarity of openings could be provided circumferentially around the shutter plate 31.

As will be appreciated by persons skilled in the art, the processor 21 then processes the sensed sensor signal 20 and correlates it with data received from a controller to thereby determine the magnitude of the electric field 3 emanating from the DC voltage source 4. The controller can operate the motor 32 and provide an appropriate timing signal to the processor 21.

As will be also be understood by persons skilled in the art, the relationship between the mechanical speed of the shutter and the electrical frequencies may be typically related by the number of shutters. For example, for a 4 shutter design, and an operating speed of 2175 rpm, the frequency of interest is 145 Hz. An upper limit is dictated by mechanical considerations such as wearing out, friction and battery life, whilst mechanical speeds over approximately 10,000 rpm may typically be unrealistic. Obviously it is desirable to increase the number of shutters, as it means a lower mechanical speed is possible whilst still having an appropriate electric frequency, however designs of 32 or more shutters may typically not be feasible.

It will be appreciated by persons skilled in the art that various circuits and/or algorithms may be used to process the sensed signal to provide the output audible/visual output to the user. The Applicant has noted that there are various considerations which may typically be adjusted according to the particular operational circumstances.

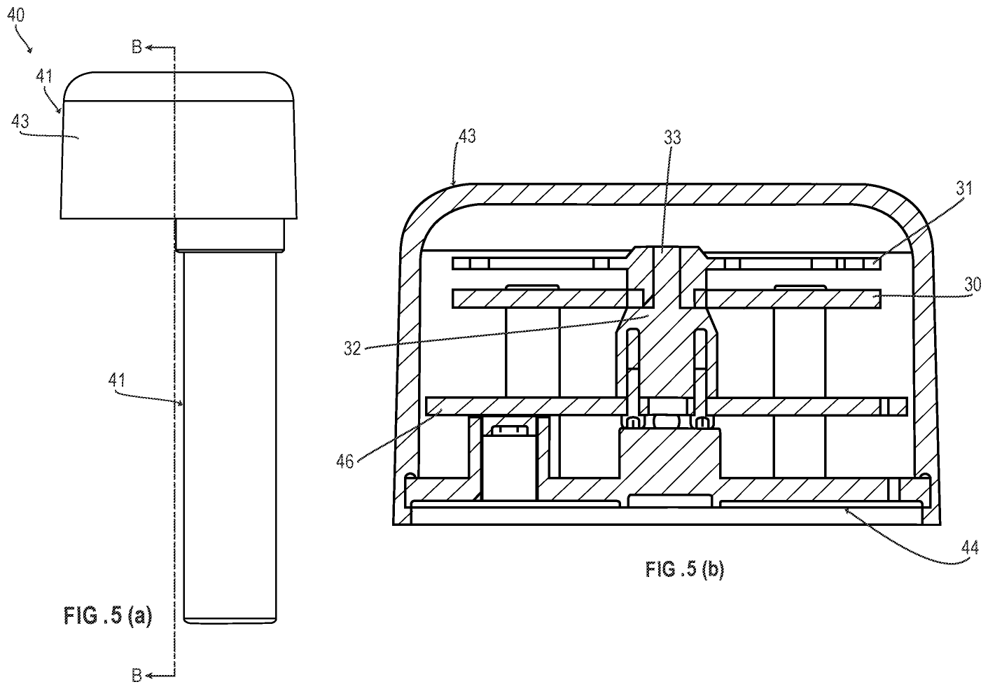

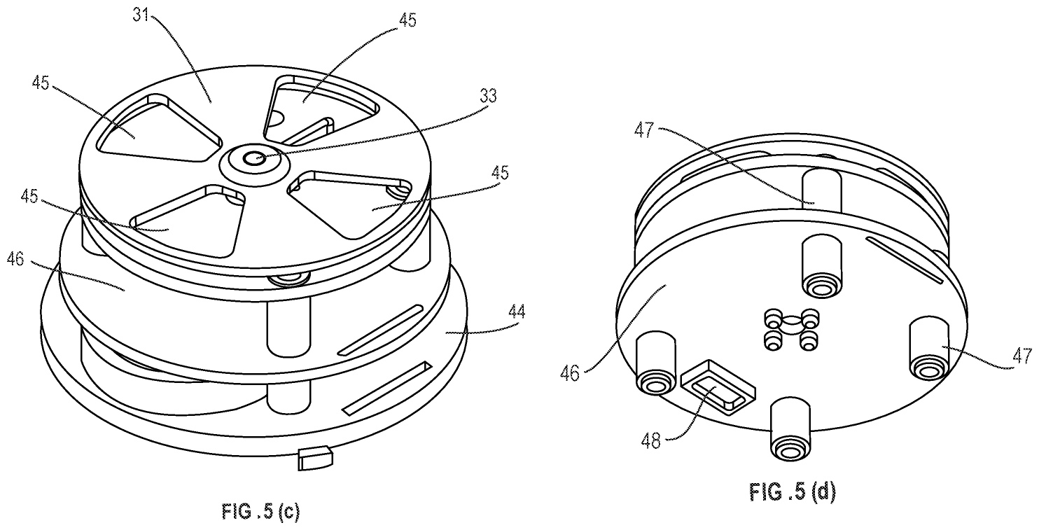

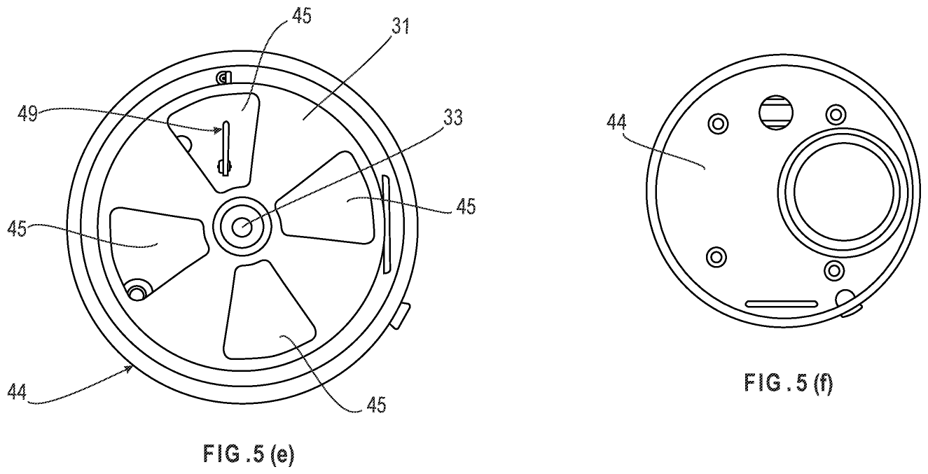

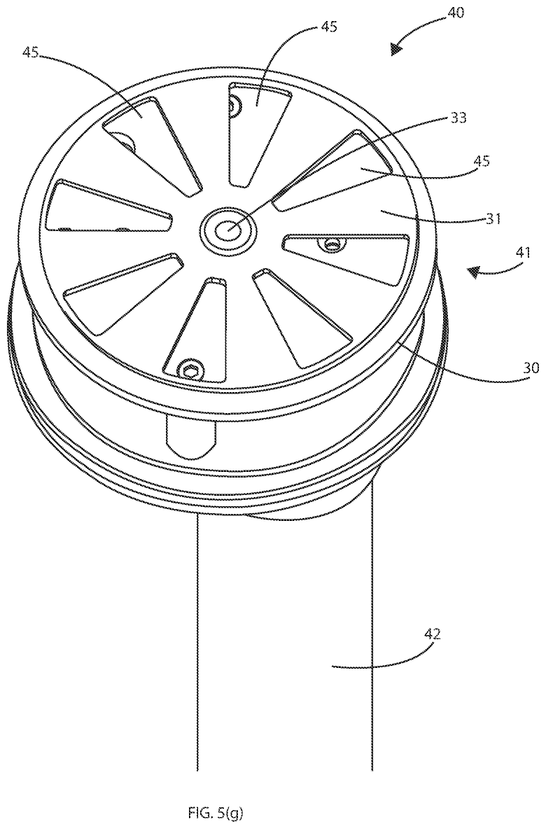

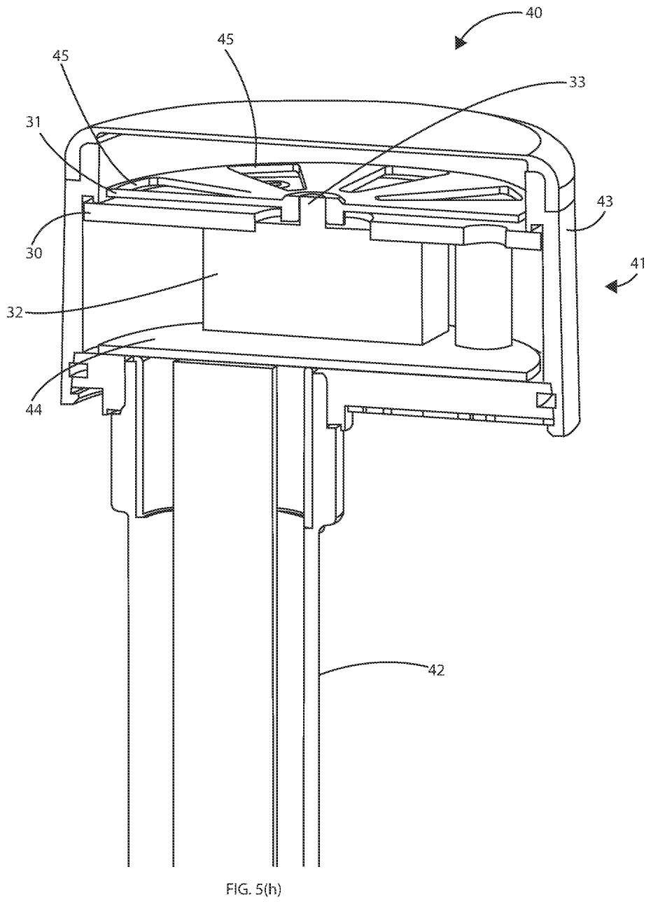

FIGS. 4 and 5 show an alternatively preferred implementation of the present invention.

An elevational view of the detector device, generally shown by the reference numeral 40, is shown in FIGS. 4 and 5, including a main body portion 41 having a handle portion 42 extending therefrom, which may be hand held by a user, so that the user may point the detector device 40 generally in the direction of a potential DC voltage source which is to be detected.

The main body 41 may be formed with a cap 43. The cap 43 may be removable, and may be at least partly formed of translucent material so as to allow the glow of a light from a light source thereunder, to provide a visual indication to a user of the detection of a DC voltage proximal to the device 40. When installed on the main body 41 of the device 40, the cap 43 may act as a dust cap, to minimise dust and other particulate matter falling on the sensor and other internal components, and, it may be optionally removed by the user as desired, for example, when a more sensitive reading is required to be obtained.

The handle portion 42 of the detector device 40, is adapted to be held by a user, and, may be optionally extendable or be adapted to attach to an extension handle, such that the user does not need to get too close to any potentially dangerous DC power source. The handle 42 may include a compartment for one or more battery therein to supply power to operate the device.

The face 44 of the main body portion may include an on/off switch 45 for a user to power the detector 40 on or off. A sensitivity switch 46 may also be provided for a user may select one or more sensitivity setting according to the magnitude of the DC voltage source being detected.

The sensitivity switch 46 may be a simple two way switch to alternatively select a high or low sensitivity, or, may include multiple sensitivity settings, which a user may select according to the strength of the DC voltage source.

A ‘start’ switch 47 may additionally be provided, which may typically be activated by a user when ready to perform either a ‘self-test’ routine and/or a ‘detection’ routine.

For example, a ‘self-test’ routine may be initially performed by a user to check that the detector is functioning correctly, that the LED array is working properly, etc. An example test routine may typically include the each LED of the array being turned on, and a buzzer sound emanating from a speaker 49 provided on the device.

An indicator LED 50 may additionally be provided to indicate when the device is switched on, and/or, when the battery is low, etc. For example, the LED may flash green to indicate that the battery is good, or red if the battery needs charging.

An array of LEDs 48 may be provided to give the user a visual indication of the strength of the detected DC voltage, via the illumination of some or all of the LEDs 48. Additionally or alternatively, an audible signal may be emitted via speaker 49, the volume of the signal optionally being variable depending on the strength of the detected DC source and/or the electric field therearound.

Rather than simply providing an array of LEDs to indicate a strong or weak DC voltage source being detected, in alternative embodiments, a meter or numerical display, indicative of the actual strength of the electric field, or, of the measured DC voltage source detected, may be displayed. Persons skilled in the art will appreciate and readily understand the appropriate processing circuity which could be provided in such embodiments to implement these types of quantitative displays.

The handle 42 and/or the main body 41 of the detector 40 may be provided of varying length, or with an extension handle, such that the detector device may be safely positioned and pointed towards the DC voltage source, whereby the user may remain a safe distance from any potentially hazardous DC voltage source, thereby minimising any safety risk to the user.

As shown in FIG. 5(b), which is a sectional view through line B-B of FIG. 5(a), the internal components of the main body portion 41 may, in one preferred implementation, include the sensor plate 30 and shutter 31. The shutter 31 is adapted to be rotated by the actuator or motor 32 via the shaft 33.

In FIGS. 5(c) and 5(e) are shown isometric and top views of the shutter. The shutter is shown into be embodied as a circular disc 31 having a plurality of openings 45 therein. In particular, the embodiment illustrated in FIGS. 4 and 5 shows the circular disc shutter 31 having four openings 45 therein. The shutter 31 is adapted to spin, such that the electric field 3 emanating from the DC voltage source 4 periodically passes through the openings 45 and is detected by the sensor plate 30.

Whilst the embodiment of FIGS. 4 and 5 shows a spinning shutter, moved via motor 32, the shutter may alternatively be adapted to move back and forth rather than spinning in a single direction. A device of this type may, in some embodiments, be implemented on a small scale, for example, to be the size of a microchip.

The embodiment in FIGS. 4 and 5 shows the motor 32 secured to the base plate 44. Also shown is the provision of a circuit board 46 for installation of the processor components or the like thereon. The circuit board 46 may likewise be installed on the base plate 44 or in another portion of the main body 41.

Persons skilled in the art will understand that appropriate contactors etc. will be provided to allow for the spinning of the shutter plate 31, etc., details of which will not be described herein.

In FIG. 5(d) is illustrated an underneath view of the circuit board 46 showing the provision of various spaces 47 to permit the various components to be installed together, and other componentry such as a speaker or buzzer 48 to provide an audible warning to the user.

FIG. 5(f) shows an underneath view of the base plate 44 which may incorporate various switches and control panels for turning the device on and off, for alternating between high and low sensitivity modes, for including visual displays output sound devices, and other componentry which would be normally formed on the control panel.

FIG. 5(g) shows an isometric view of the main body parts of the detector 40, connected to the handle 42.

FIG. 5(h) shows a partially cut away, or cross-sectional view of the main component parts of the detector 40.

An exemplary operation of the device shown in FIGS. 4 and 5 will now be described, noting that, various alternative operating steps may be performed to achieve a similar result, as will become apparent to persons skilled in the art.

A user may typically initially remove the dust cap 43 from the main body 41, before turning the detector device 40 on, by activating the on/off switch 45. To indicate to the user that the device is on, a first LED 48, for example the left hand side LED, on the LED array may illuminate, typically in a red colour.

The user may then press the sensitivity switch 46 to sequentially illuminate each of the other LEDs in a clockwise manner. In this exemplary arrangement, the left hand side LED may indicate the most sensitive setting, and the right hand side LED may indicate the least sensitive setting. Generally, until the magnitude of the DC voltage source being detected is known, the user should typically select the most sensitive setting.

The user may then typically select the self-test/start button, so that the detector device is operational and then ready to perform the detection process/routine.

The device may typically be configured so that, at any time, whilst the device 40 is on, the user may push the self-test button, to verify that the device 40 is functioning correctly. When this is performed, depending on the sensitivity selected, a selected number of the LEDs 48 will illuminate, and the buzzer 49 will sound.

If the tester lights come on and the audio buzzer sounds instantly, then this is indicative that the detector 40 is detecting the presence of a DC voltage source.

An antistatic spray may be optionally applied to the device by wiping the device to remove any static electricity which may be present.

The detector may then be switched off then on again by depressing the power button 45, and then the sensitivity switch 46 may be depressed to adjust/decrease the sensitivity, which will be indicated by appropriate illumination of the next LED.

When the user is ready to approach a potentially live DC voltage source, the user holds the device 40 by the handle 42 and points the main body portion 41 of the detector 40 towards the DC voltage source.

As the detector 40 is moved closer to the DC voltage source, the array of LEDs 45 light up from left to right, i.e. in the clockwise direction, and an audio sound may be heard by the user via the piezo device or other speaker 41.

When all the LEDs 48 illuminate, the piezo buzzer/speaker 49 will sound constantly, indicating the presence of the DC voltage source.

As the detector 40 is moved away from the DC voltage source, the LEDs 48 will progressively dim and/or go out, and the buzzer/speaker 41 will quieten, until the detector 40 is removed from the electric field.

It will be appreciated by persons skilled in the art that there are a wide variety of applications for which the detector device of the present invention may be used. By way of example, the device may be used in a variety of uses, as follows:
Detection of electric fields emanating from any active DC voltage source, typically above about 50V DC;
Static Electricity present on almost any surface, typically above about 10V and typically up to about 10kV
Solar panels, typically 600 to 800 V;
Electric Vehicles, typically 200 to 400 V (Existing vehicles use two 200 V packs, however it is anticipated that the future would see voltages increase to about 800 V at the upper end);
Heavy rail, typically 1500 V overhead lines;
Electric Trams;
Underground Mining Vehicles;
Power Stations;
Control and Switch Gear;
Under sea DC Power lines;
High Voltage DC buses, typically around 600V DC, typically found on some industrial sites, such as coal power stations and mines for diesel generator backups;
DC machines typically used for starting these diesel generators; or,
High voltage transmission lines, typically up to about 1000 kV.

It will also be appreciated that whilst the device of the present invention has hereinbefore described has been described as a DC voltage detector, that the device is capable of detecting any ‘static charge’ which is present on any object. As such, throughout this specification, the terms ‘static voltage’ and ‘DC voltage’ should be considered to be used interchangeably, and these terms should be considered to encompass the DC charge on an object, or, the electrostatic charge on an object which may have been charged by a DC voltage source.

It will also be appreciated that the DC detector device of the present invention may be combined with other devices, including, but not limited to, an AC Voltage detection device and/or a static electricity detector device.

It will be understood that the invention disclosed and defined herein extends to all alternative combinations of two or more of the individual features mentioned or evident from the text. All of these different combinations constitute various alternative aspects of the invention.

While particular embodiments of this invention have been described, it will be evident to those skilled in the art that the present invention may be embodied in other specific forms without departing from the essential characteristics thereof. The present embodiments and examples are therefore to be considered in all respects as illustrative and not restrictive, and all modifications which would be obvious to those skilled in the art are therefore intended to be embraced therein.

1. A non-contact detector adapted to detect and warn a user of the presence of an object charged by a DC voltage source, the detector including:
a housing, adapted to be hand held by the user to be positioned proximal to, but without contacting, the object;
a sensor within said housing, said sensor configured to sense an electric field emanating from the object and generate a sensor signal indicative of the strength of any sensed electric field waves, the sensor including:
a sensor plate adapted to sense said electric waves emanating from the DC voltage source; and,
a shutter disposed proximal to the sensor, adapted to periodically impede said electric field waves being received on said sensor plate, the shutter including a circular disc having at least one opening therein;
a motor adapted to operate said shutter to thereby periodically substantially block said sensor plate from sensing said electric field emanating from said DC voltage source, such that, as said shutter rotates, the electric field emanating from the DC voltage source is periodically permitted to pass through said opening(s) such that said sensor plate periodically accumulates charge and subsequently discharges to thereby generate said sensor signal;
a controller, adapted to control a periodic operation of the shutter and/or sensor plate;
a processor within said housing, adapted to receive said sensor signal from said sensor, and produce an alert signal indicative of the magnitude of the sensed electric field; and
an alert indicator on said housing, adapted to provide an indication to the user of the magnitude of the charge on the object, such that the variations of magnitude measurements of the alert indicator can be used to locate said object.

2. The detector as claimed in claim 1, wherein said sensor includes a sensor plate adapted to periodically conduct and thereby generate said sensor signal.

3. The detector as claimed in claim 1, wherein said sensor includes a sensor plate adapted to periodically move/vibrate in a direction substantially to and from said DC voltage source, so as to generate said sensor signal.

4. The detector as claimed in claim 1, wherein said alert indicator is adapted to provide an audible, visual and/or haptic alert signal to said user.

5. The detector as claimed in claim 1, wherein said processor processes said sensor signal and correlates it with data received from said controller to thereby determine a magnitude of the electric field emanating from said DC voltage source.

6. The detector as claimed in claim 1, wherein said alert indicator includes an array of lights, LEDs or the like to provide a visual indication of the magnitude of the DC voltage source.

7. The detector as claimed in claim 1, wherein said detector includes a sensitivity selection switch, for user selection according to the magnitude of the DC voltage source being detected.

8. The detector as claimed in claim 1 further includes a detector adapted to detect the presence of an AC voltage source.

9. A non-contact DC voltage detector adapted to detect and warn a user of the presence of a DC voltage, the detector including:
a housing, adapted to be hand held by the user to be positioned proximal to a DC voltage source;
a sensor within said housing, said sensor configured to sense an electric field emanating from said DC voltage source and generate a sensor signal indicative of the strength of the sensed electric field waves, the sensor including:
a sensor plate adapted to sense said electric waves emanating from the DC voltage source; and,
a shutter disposed proximal to the sensor, adapted to periodically impede said electric field waves being received on said sensor plate, the shutter includes a circular disc having at least one opening therein;
a motor adapted to operate said shutter to thereby periodically substantially block said sensor plate from sensing said electric field emanating from said DC voltage source, such that, as said shutter rotates, the electric field emanating from the DC voltage source is periodically permitted to pass through said opening(s) such that said sensor plate periodically accumulates charge and subsequently discharges to thereby generate said sensor signal;
a controller, adapted to control a periodic operation of the shutter and/or sensor plate;
a processor within said housing, adapted to receive said sensor signal from said sensor, and produce an alert signal indicative of the magnitude of said DC voltage source; and
an alert indicator on said housing, adapted to provide an indication to the user of the magnitude of the DC voltage source, such that the variations of magnitude measurements of the alert indicator can be used to locate the DC voltage source.

10. The detector as claimed in claim 9, wherein said sensor includes a sensor plate adapted to periodically conduct and thereby generate said sensor signal.

11. The detector as claimed in claim 9, wherein said sensor includes a sensor plate adapted to periodically move/vibrate in a direction substantially to and from said DC voltage source, so as to generate said sensor signal.

12. The detector as claimed in claim 9, wherein said alert indicator is adapted to provide an audible, visual and/or haptic alert signal to said user.

13. The detector as claimed in claim 9, wherein said processor processes said sensor signal and correlates it with data received from said controller to thereby determine a magnitude of the electric field emanating from said DC voltage source.

14. The detector as claimed in claim 9, wherein said alert indicator includes an array of lights, LEDs or the like to provide a visual indication of the magnitude of the DC voltage source.

15. The detector as claimed in claim 9, wherein said detector includes a sensitivity selection switch, for user selection according to the magnitude of the DC voltage source being detected.

16. The detector as claimed in claim 9 further includes a detector adapted to detect the presence of an AC voltage source.

17. (canceled)

18. (canceled)

19. (canceled)

20. (canceled)

21. (canceled)

22. (canceled)

23. (canceled)

24. (canceled)

25. (canceled)

26. (canceled)
